(19) United States
(12) Patent Application Publication
(10) Pub. No.: US 2017/0030474 A1
(43) Pub. Date: Feb. 2, 2017

(54) PINCH VALVE

(71) Applicant: I.P.U. INDUSTRIES LTD, Yavne (IL)

(72) Inventor: Eyal BEN-AMI, Yavne (IL)

(21) Appl. No.: 15/302,240

(22) PCT Filed: Apr. 5, 2015
(86) PCT No.: PCT/IB2015/052475

§ 371 Date: Oct. 6, 2016

Related U.S. Application Data
(60) Provisional application No. 61/976,007, filed on Apr. 7, 2014.

(51) Int. Cl. F16K 31/00; H01L 41/09; H02N 2/06; F16K 7/04; F16K 37/00

(52) U.S. Cl. CPC F16K 31/004; F16K 7/045; F16K 37/0083; H02N 2/06; H01L 41/09

(57) ABSTRACT

The present invention relates to pinch valves and in particular to such pinch valves controlled with a piezoelectric linear actuator assembly for controlling the flow through a flexible tube disposed within a pinch valve body by controlling the position of a plunger relative to a flexible tube at a control point along the length of said tube.

### FIELD OF THE INVENTION

The present invention relates to pinch valves and in particular to such pinch valves controlled with a piezoelectric linear actuator.

### BACKGROUND OF THE INVENTION

Valves and valve systems have been designed in the past having a valve actuated by a solenoid, piezoelectric stack or magneto-restrictive rod to control the flow of fluid through the valve system.

One controllable valve type is a pinch valve that utilizes a pinching effect to obstruct fluid flow through a flexible conduit or tube. Flow through the tube is controlled by constricting the cross-sectional area of the tube with a plunger. The plunger itself may be driven and/or actuated and/or controlled with a different control modules and actuators.

Control of the actuators that in turn control the flow through the flexible tube is difficult with state of the art pinch valves that generally utilize solenoid actuators. Accurate control of various parameters associated with the pinch valve is not provided with state of the art pinch valves.

The lack of accurate control is generally due to the difficulty in a solenoid driven valve to maintain holding position particularly in intermediate positions where it is not a matter of the valve assuming the off position or on position, rather an in-between state as is often the case with pinch valves.

However, in solenoid-controlled valve systems, it is often difficult to accurately control movement and positioning of the valve member through the control signals applied to the solenoids. This is especially true when intermediate positioning of a solenoid-controlled valve for example between the closed state and the open state, and maintained in a fixed position is desired.

Current pinch valves are further prone to overheating, saturation, and exhibit hysteresis, all leading to inaccuracies with respect to controlling the flow through the flexible tube such that the valve does not react linearly with respect to a control signal. Such factors lead to unpredictability of the valve and lack of true flow control through the valve body.

Other drawbacks of current pinch valves is their inability to generate high holding forces and therefore provide valves with only low holding force that are not suitable for applications requiring larger holding forces.

### SUMMARY OF THE INVENTION

The present invention overcomes the deficiencies of the background by providing a pinch valve utilizing a linear piezoelectric actuator module comprising an assembly of at least one or more piezoelectric linear actuator that provides for controlling fluid flow through a flexible conduit. Preferably the piezoelectric control module provides a linearly that does

Preferably the pinch valve comprises at least one or more controllable piezoelectric actuators. Most preferably the piezoelectric actuators provide a linearly controllable pinch valve where the flow through the valve may be controlled linearly and predictably controlled in proportion to a control signal. Most preferably the control signal and/or activating energy applied to the piezoelectric actuating module are linearly proportional with the flow through the valve body. For example, in order to obtain a certain flow ‘F’ through a valve body a specific and predictable control signal and/or activation signal ‘S’ is required, therein defining a linear slope (‘m’) on a Flow vs. Signal Input graph. A linearly proportional slope (‘m’) provides for changing the fluid flow rate through a flexible conduit as a consequence of a direct and linear change to the input signal utilized by fluid control module or gating actuation module that is in turn, governed by the predefined slope (‘m’) of Flow vs. Signal Input graph specific to at least one or more of the pinch valve, flexible conduit.. Accordingly a truly linear valve is provided with predictable flow through the flexible conduit based on a predictable control signal providing by the gating actuation module of the present invention.

An example of a piezoelectric actuator referenced and illustrated herein, may optionally and most preferably be realized in the form of the piezoelectric actuator described in U.S. Pat. No. 7,498,719 to Piotr et al, that is incorporated herein by reference as if fully set forth.

Within the context of this application the term fluid refers to any flowing fluid in various states for example including but not limited to liquids, gases, air or the like.

Most preferably the valve control module according to the present invention comprises an encoder to increase valve linearity, and to ensure resolution of the linear valve therein minimizing the potential valve hysteresis effect.

Most preferably, the pinch valve piezoelectric actuator module according to optional embodiments of the present invention may be turned on or off without a lag or phase.

Optionally and preferably the pinch valve according to the present invention provides a valve assembly that may exert a holding force of at least about 1 kg or more. Optionally and preferably the valve and particularly the valve control and/or gaiting module according to the present invention may be configured to provide a holding force from about 100 g up to about 2 kg, from about 100 g-500 g; 500 g-1000 g and up to about 2 kg.

An optional embodiment of the present invention provides a piezoelectric pinch valve that provides a bi-directional piezoelectric actuator that may move a load along a valve stem and/or plunger in response to a control signal.

An optional embodiment of the present invention provides a piezoelectric valve that does not require a return spring, most preferably as the piezoelectric actuator maintains its position about the piezoelectric actuator shaft without exerting additional energy, as seen with solenoid valves.

An optional embodiment of the present invention provides a piezoelectric control module that may be retrofit to replace a pinch valve gating control modules while maintaining the pinch valve housing and in particular the flexible tube.

Optionally and most preferably the piezoelectric control module according to the present invention provides a valve gating module that provides a control module that most preferably runs on low energy means. Optionally low energy means may for example include but is not limited to battery, photovoltaic cells, solar panels, rechargeable batteries, the like or any combination thereof.

Optionally and most preferably the control module according to the present invention provides for a valve that readily dissipates heat and/or does not overheat under standard working conditions.

An optional embodiment of the present invention provides a piezoelectric control module that may be retrofit with an existing pinch valve housing , to convert it to a linear and/or proportional valve.

An optional embodiment of the present invention provides a piezoelectric controllable valve, utilizing a control signal that utilizes minimal energy requirements while providing maximal holding force, for example up to about 2 kg, optionally from about 100 g , 200 g, 300 g, 400 g, 500 g, 600 g, 700 g, 800 g, 900 g, 1000 g, 1100 g, 1200 g, 1300 g, 1400 g, 1500 g, 1600 g, 1700 g, 1800 g, 1900 g, 2000 g.

Optionally and preferably piezoelectric pinch valve gating module according may be customized and/or adapted and/or fine-tuned to meet at least one or more valve requirements for example including but not limited to flow rate, energy dissipation, thrust, holding force, flexible tube cross-sectional diameter, the like or any combination thereof.

Optionally and preferably the gating/control module may be customized and/or configured so as to provide the necessary holding force according the pinch valve requirements and/or the flexible tube properties.

Optionally a valve control signal may be provided by at least one or more processor and/or controller for example including but not limited to an internal controller and/or external controller and/or auxiliary controller, any combination thereof.

Optionally and preferably an external controller and/or auxiliary controller may be utilized in conjunction with an internal controller to drive and control the piezoelectric valve according to the present invention. For example, a remote valve control signal may be generated by a user with an external controller and communicated to an internal controller to control the piezoelectric valve according the present invention.

Optionally internal controller may be driven with a power source and/or electronics for example including but not limited to battery, rechargeable battery, induction circuit, mains power supply, electronic circuitry, photovoltaic cells, DC power, AC power, or the like power supply as is known and accepted in the art.

Within the context of this application the term valve stem may be interchangeable with the term plunger, shaft, and moveable shaft.

Within the context of this application the term valve gating or valve gating module refers to the member of the valve required for controlling the valve opening and closing.

Within the context of this application the terms proportional valve opening refers to controlling the valve open and/or close state in a proportional manner providing for gating the valve in a variable manner between 0-100% (zero and 100 percent). Optionally the term proportional opening may be interchangeably used with the term non-discrete and/or continuous control of the valve opening.

Embodiments of the present invention provide for the linearity by employing a controllable linear piezoelectric actuator. The linear piezoelectric actuator provides the appropriate (required) holding force, to control the flow through the valve body, without exerting additional power and/or energy, such that the valve's gating module's start and stop positions (valve stem position relative to the constant valve seat position) are linearly predictable, configurable, repeatable and controllable.

Optionally and most preferably a controller and/or processor and/or microprocessor may be provided as part of the valve gating control module to optionally elucidate and/or determine the linear relationship between the Flow ‘F’ and control signal ‘S’ for example in the form of slope (‘m’) as previously described. Optionally the ‘F’ vs. ‘S’ relationship is continuously updated and configured to maintain a linear relationship. Optionally gating control module may signal and/or communicate problems, for example to a user, with the valve in any portion thereof if the linear relationship is not maintained within a given range for example within one or two standard deviations.

Embodiments of the present invention may be realized in a number of application involving a pinch valve, pump and/or fluid pump and/or hydraulic pump, for example including but not limited to a valve for gating any flowing fluid (liquids, gasses, oils, plasma) through a flexible conduit for any application such as medical application, industrial application, automotive industry, healthcare industry, chemical industry, manufacturing, mass production, home-use application, personal application, any combination thereof or the like.

Optionally the pinch valve assembly according to the present invention may comprise at least one or more flexible conduit and/or tube through which a flowing fluid may controllably flow. Optionally the pinch valve assembly may comprise two or more flexible conduits through which a flowing fluid may controllably flow. Optionally the pinch valve assembly may comprise a plurality of flexible conduits through which a flowing fluid may controllably flow. Most preferably flow control through the at least one or more flexible conduits and/or tube is provided with at least one or more piezoelectric linear actuator assembly according to the present invention. Optionally each flexible conduit may be controlled with a single piezoelectric linear actuator assembly. Optionally a plurality of flexible conduit may be controlled with a single piezoelectric linear actuator assembly.

Optionally flow through at least one or more flexible conduits and/or tube may be controlled with at least one or more piezoelectric linear actuator assembly controlling at least one or more plungers. Optionally flow through at least one or more flexible conduits and/or tube may be controlled with at least two piezoelectric linear actuator assemblies. Optionally flow through at least one or more flexible conduits and/or tube may be controlled with a plurality of piezoelectric linear actuator assemblies.

Optionally flow through at least one or more flexible conduits and/or tube may be controlled with at least one or more piezoelectric linear actuator assembly disposed along at least one or more segments along the flexible conduit and/or tube.

Optionally flow through at least one or more flexible conduits and/or tube may be controlled with at least one or more piezoelectric linear actuator assembly disposed along at least two segments and/or control points forming at least two constriction sites that are disposed along the length of the flexible conduit and/or tube. Optionally the at least two control points may be opposite one another, for example forming an upper constriction site and lower constriction site , along the same control point and/or segment of the flexible conduit therein forming a double pinch valve. Optionally the at least two or more control points may be sequential and/or intermittently placed along the length of the flexible tube therein forming a sigmoidal gated segments.

Optionally the pinch valve assembly is controlled with the piezoelectric linear actuator assembly and control flow through the flexible conduit and/or tube to have a flow rate from 100% of flow (full flow) to 0% of maximal flow (no flow) and may be controlled to be about 10%, 15%, 20%, 25%, 30%, 35%, 40%, 45%, 50%, 55%, 60%; 65%, 70%, 75%, 80%, 85%, 90%, 95% of the flow.

Optionally the flexible conduit and/or tube may be provided in different dimensions (diameter) and/or material and/or the like properties, accordingly the controlling piezoelectric linear actuator assembly may be customized and/or adjusted to accommodate the flexible tube property for example including but not limited to the tube type, size, material, dimensions, or the like properties of the flexible tube and/or conduit.

Unless otherwise defined, all technical and scientific terms used herein have the same meaning as commonly understood by one of ordinary skill in the art to which this invention belongs. The materials, methods, and examples provided herein are illustrative only and not intended to be limiting. Implementation of the method and system of the present invention involves performing or completing certain selected tasks or steps manually, automatically, or a combination thereof.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in order to provide what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1A-C are schematic block diagrams of exemplary pinch valves, fit with a piezoelectric valve control module according to an optional embodiment of the present invention;

FIG. 2A-C show various views of a pinch valve fit with a piezoelectric control module according to an optional embodiment of the present invention; FIG. 2A shows a perspective view of a pinch valve; FIG. 2B shows a cross-sectional view; FIG. 2C shows an exploded view;

FIG. 3 shows a close up view of the piezoelectric linear actuator utilized in the piezoelectric control module according to the present invention; and

FIG. 4A-B are various views of a schematic illustrative diagram of a cross-linked piezoelectric actuator load, according to an optional embodiment of the present invention, deployed in the piezoelectric valve depicted in FIG. 2A-C; FIG. 4A provides a perspective view and FIG. 4B provides a partial close up view.

### DESCRIPTION OF THE PREFERRED EMBODIMENTS

The principles and operation of the present invention may be better understood with reference to the drawings and the accompanying description. The following figure reference labels are used throughout the description to refer to similarly functioning components are used throughout the specification hereinbelow:

10 pinch valve housing;

10a pinch valve upper housing;

10b pinch valve lower housing;

10d dual pinch valve housing;

12 pinch valve flexible tube;

14 pinch valve plunger recess;

16 OTC pinch valve plunger;

20 auxiliary valve control module;

20s auxiliary control module signal;

50 retrofitted pinch valve assembly;

52 auxiliary control valve system;

54 pinch valve assembly

56 dual pinch valve assembly;

100 piezoelectric valve control module;

101 control segment

102 control module housing;

102a-c control module housing portions;

102d control housing diaphragm seal;

104 piezoelectric actuator;

104h actuator holding plate;

104b piezoelectric actuator elastic body;

104c circuitry connectors;

104e actuator piezoelectric substrate and electrodes;

104f actuator free end;

104s actuator shaft;

105 strain gage control;

106 plunger assembly;

106a first plunger;

106b second plunger;

106e plunger end;

106p plunger piston;

106c plunger coupling adaptor

108 electronic circuitry module;

108s control signal;

110a pinch valve upper housing;

110b pinch valve lower housing;

110c pinch valve plunger upper recess;

110d pinch valve plunger lower recess;

114 cross linking load/member;

114a actuator shaft recess;

114b base member;

114c central body/core;

114d distal end;

114e extending arm;

114f,h luminal surface;

114p proximal end;

114r load valve stem recess;

114s shaft support member;

114t shaft receiving portion;

116 cross link coupling adaptor

Embodiments of the present invention provide a pinch valve assembly (50, 52, 54). Optionally and preferably the pinch valve is linearly proportional. The pinch valve comprising a pinch valve housing (10, 110) associated with a flexible conduit and/or tube 12 and a piezoelectric control module 100. Most preferably the control module utilizes a piezoelectric linear actuator 104 to control a plunger 106 that provides for pinching the flexible tube 12 to control rate of flow therethrough.

Most preferably the flow of flowing fluid flowing through flexible tube 12 is controlled with the piezoelectric control module 100 via plunger 106. Optionally fluid flow rate (‘F’) through a flexible tube (12) may be linearly and predictably controlled with a control signal ‘S’ (108s, 20s) provided with control module (100) to define the position of plunger 106 relative to flexible tube 12.

Most preferably the control signal ‘S’ (108s, 20s) may be determined and/or provided and/or configured by evaluating and/or abstracting the graph of Flow vs. Control Signal and determining the graph's slope. Optionally the slope may be specific to and/or configured according to at least one or more selected from the group consisting of pinch valve body(10, 110), control module (100), plunger 106, shape of plunger end 106e, type of flexible tube 12, materials forming the flexible tube 12, diameter of flexible tube 12, at least one dimension of flexible tube 12, the like or any combination thereof.

Most preferably the control module of the present invention provide for linearity by employing a controllable linear piezoelectric actuator (104). The linear piezoelectric actuator (104) provides the appropriate and/or required holding force, to control the degree of pinching of the flexible tube and therein controlling the flow through the flexible tube 12 disposed in pinch valve body (10, 110).

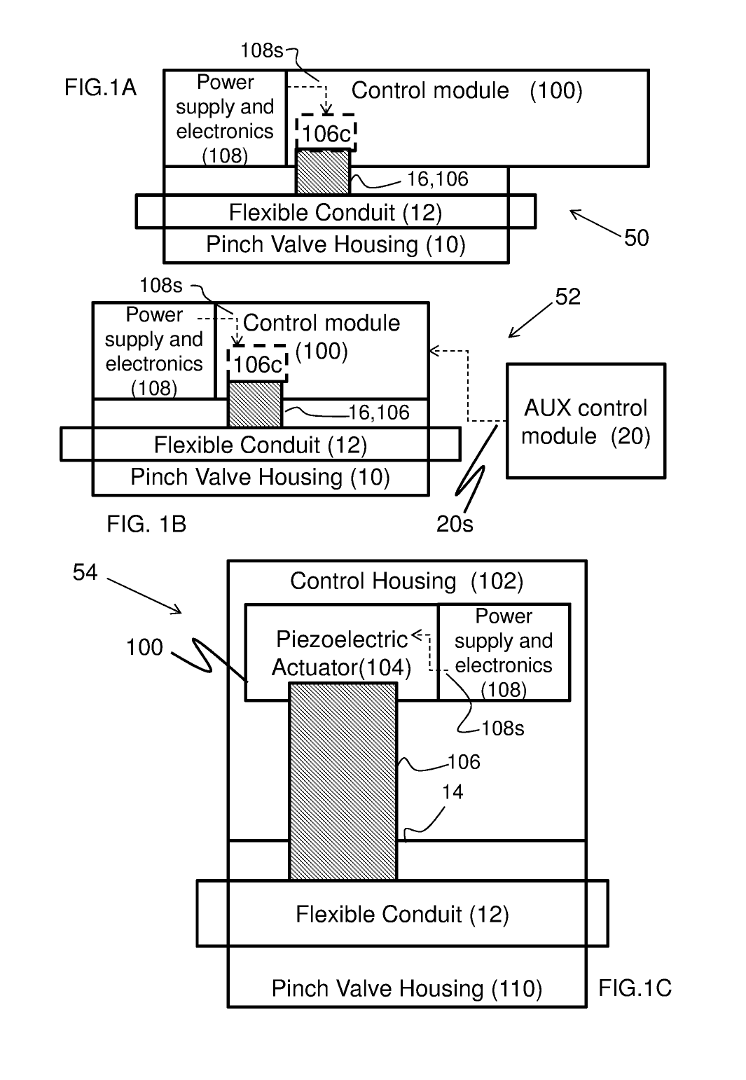

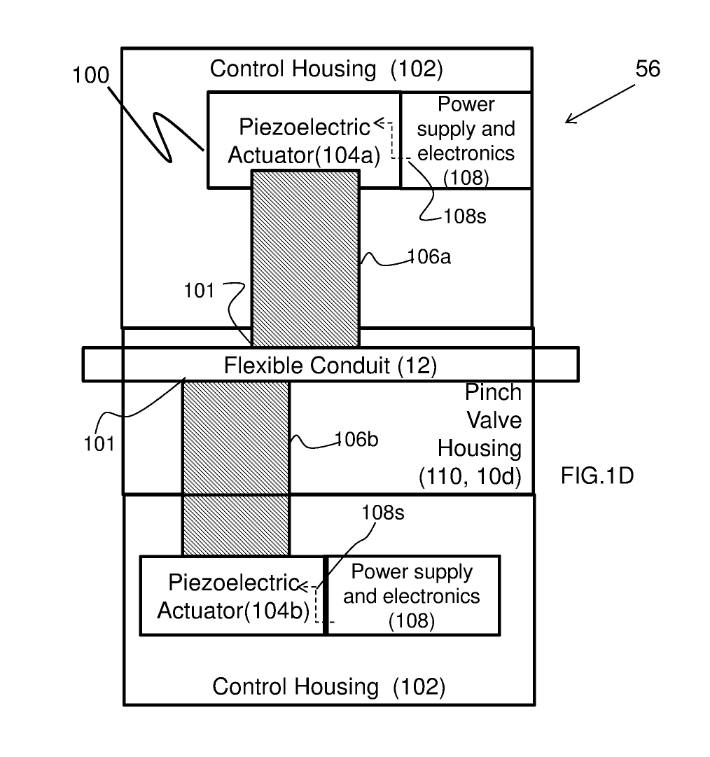

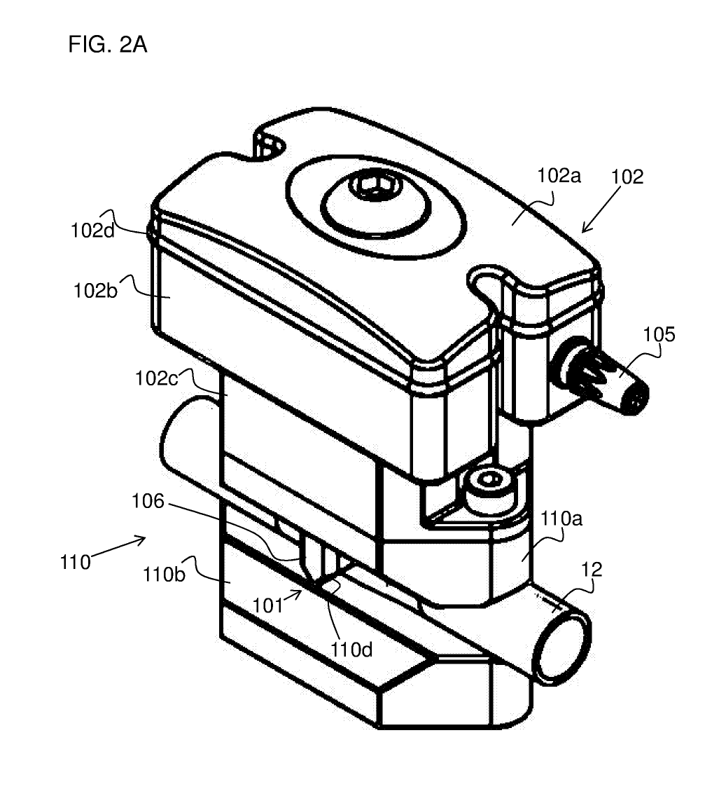

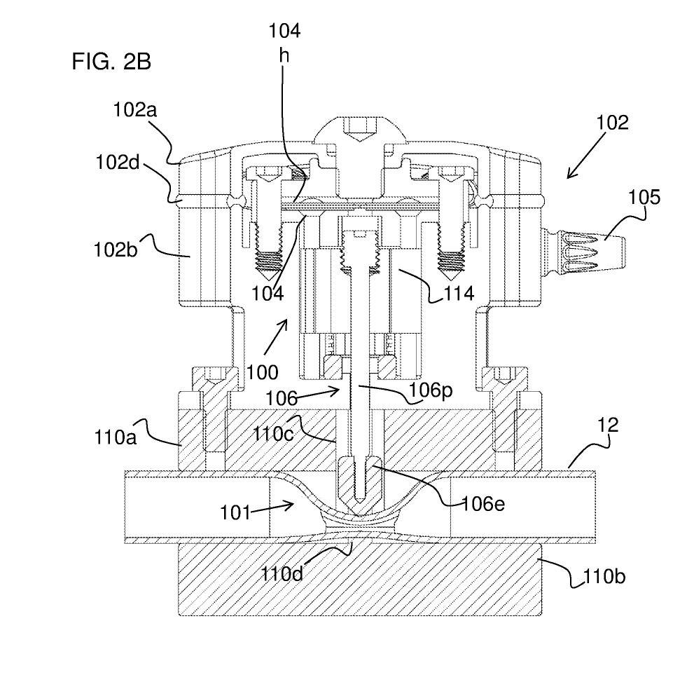

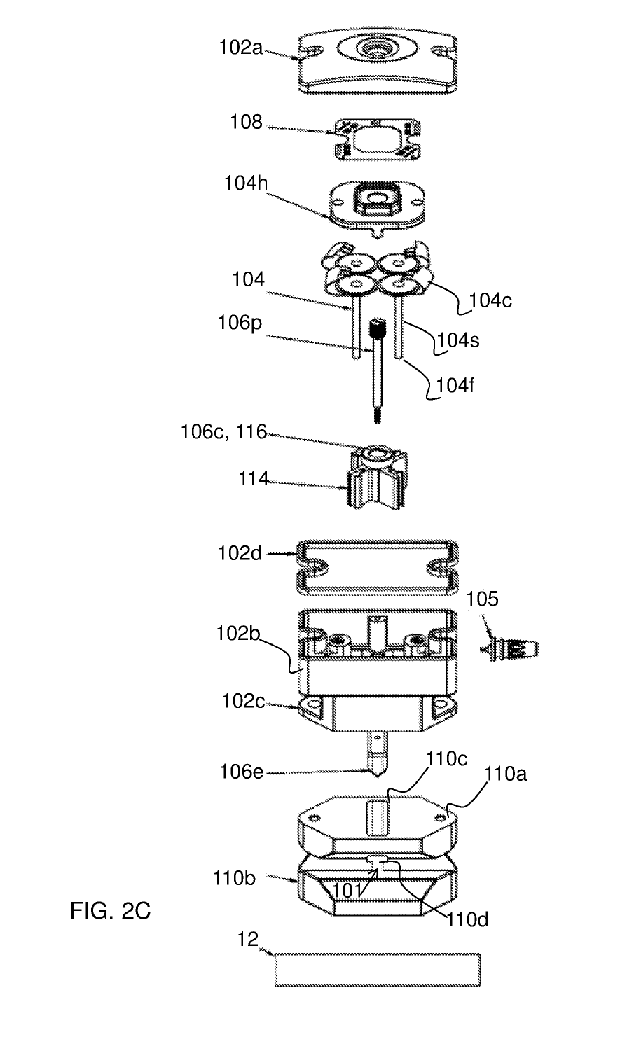

Embodiments of the present invention provide a control module 100 that may be retrofit with an “off the shelf” and/or “over the counter” pinch valve body 10, for example as shown in FIG. 1A-B. Optionally embodiments of the present invention provide a pinch valve 110 the is fit and customized and built in with a control module 100, for example as shown in FIG. 1C-D and FIG. 2.

FIGS. 1A-B show schematic block diagrams of an optional retrofitted pinch valve assembly 50, 52 comprising an “over the counter” or “off the shelf” (hereinafter ‘OTC’) pinch valve body 10 that is retrofit with a piezoelectric valve control module 100.

Preferably control module 100 is provided with a housing that may be seamlessly associated with OTC pinch valve body housing 10, along at least one or more surface. Optionally control module 100 may be provided with an internal plunger 106 that may be fit and/or associated with housing 10. Optionally control module 100 may be provided with a plunger coupling adapter 106c and/or a plunger piston 106p that may be coupled to and/or fit with an internal and/or intrinsic plunger 16 provided with OTC pinch valve housing 10.

Most preferably control module 100 functions with circuitry 108 to control plunger a plunger assembly 106, 16 where circuitry 108 provides a control signal 108s to control at least one or more piezoelectric linear actuators 104 that in turn control the position of plunger assembly 106,16 relative to flexible tube 12 disposed within OTC pinch valve housing 10. Therein control module 100 provide for controlling the flow through flexible tube 10 by way of pinching flexible tube 10 with plunger 16,106.

Optionally control module 100 may further comprise a strain gauge controller 105 (FIG. 2A-C) provided for manually adjusting and/or fine tuning the movement of plunger 16,106 relative to control signal 108s.

FIG. 1B shows a schematic block diagram of an optional pinch valve assembly 52, similar to that depicted in FIG. 1A however further comprising an auxiliary control module 20 that is

Optionally control module 100 may further provide for converting the linear movement of the piezoelectric actuators utilized therein to rotational motion, optionally and preferably to provide the appropriate circular motion required to control optional rotational grating mechanism employed by optional OTC pinch valves 10. Optionally appropriate conversion of linear motion, provided by actuator 104,to rotational motion may for example include but is not limited to gear, gear works, cam, transformer, piston, the like or any combination thereof.

FIG. 1B shows an optional configuration of retrofitted valve assembly 52, similar to that shown in of FIG. 1A however provided in the form of a dual control pinch valve assembly 52 further comprising an auxiliary valve control module 20 provided for remotely controlling and/or communicating with pinch valve assembly 52 via valve control module 100.

Optionally, external and/or auxiliary controller 20 may be utilized in conjunction with internal controller module 108 or module 100 to drive and control the pinch valve assembly 52. For example, a remote valve control signal 20s may be generated by a user with an auxiliary controller module 20 and communicated to an internal controller 108 and/or control module 100 to control pinch valve 52, to control the flow through flexible tube 12 by adjusting the position of plunger 16, 106 relative to flexible tube 12.

Optionally remote and/or auxiliary controller module 20 may be provided in optional forms for example including but not limited to a computer, mobile communication device, PDA, mobile telephone, robot, android, server, dedicated device, remote control, any combination thereof or the like device comprising processing, communication and power source capabilities. Optionally auxiliary controller module 20 may further comprise a display.

Optionally controller module 20 may communicate a control signal (20s) to valve control module 100 or electronic circuitry 108 using at least one or more communication protocols and/or technology for example including but not limited to wireless, radio frequency (RF) , infrared (IR), optical, wired, near field communication (NFC), far field communication (FFC), RFID technology, Bluetooth, acoustic, cellular, or any combination thereof.

Optionally remote and/or auxiliary controller module 20 may communicate with an internal controller module 100 or the like electronic circuitry 108 for generating and communication an internal control signal (108s) to at least one or more piezoelectric actuator 104.

Optionally remote and/or auxiliary controller module 20 may be controlled manually by a user.

Optionally and more preferably remote and/or auxiliary controller module 20 may be controlled automatically according to at least one or more triggering event, for example including but not limited to a trigger, an occurrence, an event, an alarm, a scheduled event, an unscheduled event, threshold crossing, any combination thereof or the like triggering event.

FIG. 1C-D show a schematic block diagram of an optional embodiment of the present invention for a pinch valve assembly 54, 56 comprising a pinch valve body 110 (non OTC pinch valve body) that is fluid with and a customized control module 100 to control the flow through a flexible tube 12, by way of pinching along at least one or more control segments and/or pinch segments. Most preferably the control segment and/or pinch segment is defined along the location of plunger assembly 106.

Control module 100 is provided with a housing 102 comprising at least one or more piezoelectric actuators 104 provided to control plunger assembly 106 based on a controllable single 108s provided by electronic circuitry module 108.

Most preferably piezoelectric actuator 104 and plunger assembly are associated with one another over a control segment and/or pinch segment defined along the length of flexible tube 12.

Optionally the at least one or more flow control points and/or pinch segment and/or control segments may be defined along the length of flexible tube 12 in any manner and/or position. Optionally at least two or more control points may be defined along the length of flexible tube in any manner for example including but not limited to sequentially, intermittently, opposing surfacing, the like or any combination thereof.

FIG. 1C shows pinch valve assembly 54 comprising a single control module including at least one plunger assembly 106 that is controllable with at least one or more piezoelectric linear actuator 104.

Optionally plunger assembly 106 may be configured to control flow through flexible tube 12 by way of pinching along at least one or more control points and/or pinching points and/or constriction sites.

Optionally plunger assembly 106 may be configured to control flow through flexible tube 12 by way of pinching along at two one or more control points and/or pinching points and/or constriction sites.

Optionally at least one or more plungers 106 may be utilized to control flow through tube 12 through at least one or more control points.

FIG. 1D shows a dual pinch valve assembly 56 comprising at least two or more control points that are controlled with at least two controllable plunger assembly 106 preferably controllable with at least one control module 100 and optionally with two or more control module 100 may be employed, for example as shown.

Dual pinch valve assembly 56 may comprise two control segments 101 that are monitored and/or controlled each controlled with an individual control module 100 employing two plunger assemblies 106a, 106b, disposed along individual control segments 101 that are defined along opposing surfaces and/or segments of tube 12.

Optionally the OTC pinch valve body 10 may be provided in the form or a dual pinch valve body 10d, for example as shown in FIG. 1D, wherein valve body 10 is provided with at least two or more control segments and/or control points and/or pinch points 101.

Now collectively referring to FIG. 2A-C shows optional view of an optional embodiment of a pinch valve assembly 52 for example as depicted in FIG. 1C.

FIG. 2A shows a perspective view of an optional pinch valve assembly comprising control module housing 102 including, the housing including a piezoelectric control module 100 provided to control a plunger assembly 106 relative to a flexible tube 12 fit within a pinch valve housing body 110. Flexible tube 12 is provided to allow a flowing fluid to flow therethrough while control module 100 provides a plunger with which the flexible tube is pinched to constrict the flow over a restriction point 101.

Control module 100 includes at least one or more piezoelectric linear actuator 104 that is controlled with circuitry 108 providing a control signal 108s. Most preferably actuator 104 is associated or otherwise coupled with plunger assembly 106.

Optionally control module housing 102 is provided from a plurality of optional parts for example upper portion 102a, medial portion 102b and lower portion 102c. Optionally upper portion and 102a and medial portion 102b may be coupled with a diaphragm seal 102d.

Most preferably housing 102 is coupled and/or otherwise associated with pinch valve housing 110, configured such that plunger assembly 106 is disposed over flexible tube 12 at a control point 101. Most preferably control point 101 is defined by at least one or more recess plunger recess 110c, 110d disposed in pinch valve housing 110.

Most preferably pinch valve assembly comprises a strain gauge 105 providing fine control of the force exerted with which plunger assembly 106 onto flexible tube 12 at control segment 101 to control the flow through tube 12.

Optionally and preferably pinch valve housing 110 may be provided from a plurality of segments including an upper portion 110a and a lower portion 110b. Each portion comprising a plunger recess 110c,d provided to allow plunger 106 to gain access to flexible tube 12 so as to facilitate flow control.

FIG. 2B shows a cross sectional view of pinch valve assembly depicted in FIG. 2A, shown across the length of housing 102 therein revealing the control module 100. As shown plunger assembly 106 comprises a central piston 106p that is fit and/or coupled with a plunger end 106e. End 106e is shown in an optional non limiting embodiment, shown in the form assuming a sharp edge provided to create a concise pinching point 101. Optionally end 106e may assume any shape and/or configuration as is necessary according to the required flow control and flow control application. Optionally end 106e may assume a substantially rectangular end, curved end having a configured radius, point edge any combination thereof or the like.

Most preferably plunger assembly 106 and in particular plunger piston 106p is associated with and controlled with at least one or more piezoelectric linear actuators 104. Optionally plunger assembly 106 may be controlled with an array and/or a group and/or an assembly comprising a plurality of actuators 104. Preferably plunger assembly 106 is associated with at least one or more actuator 104 with load for example cross linked member 114 the provides for coupling at least four actuators 104 with a plunger piston 106p to provide for plunger assemblies linear movement relative to flexible tube 12.

Most preferably actuators 104 are fixed within housing 102 with a fixation and/or actuator holding plate 104h, as more clearly shown in FIG. 2C.

FIG. 2C shows an exploded view of pinch valve assembly revealing the components of pinch valve housing 110, control module housing 102, control module 100 and plunger assembly 106.

Pinch valve housing 110 preferably comprises an upper housing 110a lower housing 110b. Most preferably pinch valve housing 110 comprises a recess provided for receiving and/or associating with flexible tube 12. More preferably housing 110 is associated with tube 12 along its length.

Preferably upper portion 110a comprises a plunger recess 110c defining a flow rate control point and/or segment 101. Most preferably recess 110c provides for allowing plunger assembly 106, 106a to reach the pinching surface disposed on tube 12.

Optionally lower portion 110b may comprise a plunger receiving recess 110d for receiving plunger end 106e. Optionally recess 110d may be provided for securely pinching flexible tube 12 at control segment 101. Optionally in a dual pinch valve assembly, for example as shown in FIG. 1D, recess 110d may provide for receiving a second plunger 106b therein defining a second control segment 101.

Most preferably pinch valve housing 110 and control housing 102 may be coupled along at least one surface for example upper portion 110a may be coupled and/or securely associated with at least apportion of housing 102 for example lower portion 102c.

Control module housing 102 as shown in FIG. 2C comprises a plurality of segments including an upper portion 102a, medial portion 102b and lower portion 102c, where a seal 102d is utilized to seal portions 102a and 102b.

Optionally lower portion 102c is coupled with and/or otherwise associated with plunger end 106e. Optionally lower portion 102c is fit with and/or continuous with plunger end 106e. Optionally lower portion 102c may be provided in various configurations as a function of plunger end 106e, wherein portion 102c is may be readily exchanged in a modular fashion so as to allow reconfiguration of the pinch valve according to the plunger end 106e required for particular pinch valve applications.

For example a plurality of optional interchangeable lower portion 102c may be provided each having a distinct plunger end 106e configuration.

Optionally a plurality of optional interchangeable plunger ends 106e may be provided to be readily interchanged by way associating and/or disassociating with lower portion 102c according to the required pinch valve application and/or any pinch valve parameter performance parameters. Optionally end 106e may be provided in optional configuration and/or shapes as is necessary according to pinch valve requirements and/or parameters for example including but not limited to the required flow control, diameter of flexible tube 12, materials of tube 12, and flow control application. Optionally end 106e may assume a substantially rectangular end, curved end having a configured radius, point end any combination thereof or the like.

Optionally at least one or both of plunger end 106e and/or lower portion 102c may be configured according to at least one or more pinch valve assembly parameters and/or requirements for example including but not limited to flexible tube size 12, diameter of flexible tube 12, type of flexible tube 12, materials forming the flexible tube 12, the like or any combination thereof.

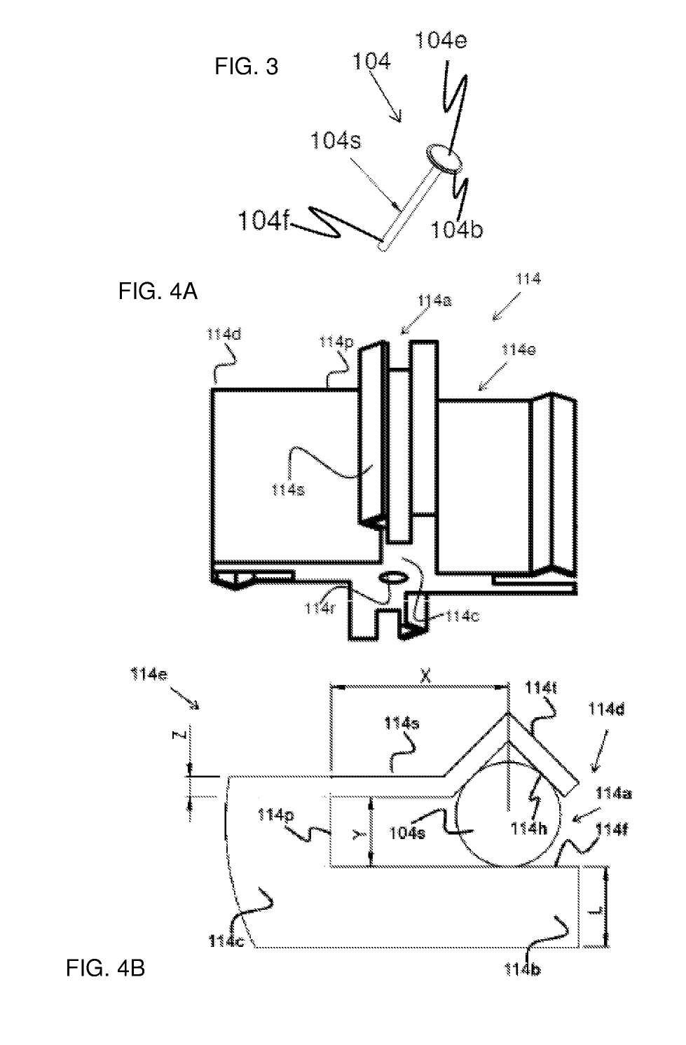

Plunger assembly 106 most preferably comprises piston 106p and end 106e. Most preferably the linear position of plunger assembly 106 relative to flexible tube 12 is controlled with at least one or more linear actuators 104, and more preferably with a plurality of 104, shown in greater detail in FIG. 3, that are cross linked with one another with member 114, shown in greater detail in FIG. 4A-B.

Most preferably plunger assembly 106 is configured to control flow through flexible tube 12 by constricting tube 12 along at least one or more constriction and/or control segments 101, therein pinching flexible tube 12 at control segment 101 in a controllable manner. Most preferably the degree with which plunger 106 pinches tube 12 is determined by the position of plunger 106 which is controlled with at least one or more linear actuator 104 that is coupled or otherwise associated with plunger 106.

Preferably plunger assembly 106 is coupled or otherwise associated with at least one or more actuator 104 via piston 106p. Optionally piston 106p may be directly and/or indirectly associated with at least a portion of actuator 104, for example directly associated along its shaft 104s or either indirectly via a cross linking member 114 as shown.

Optionally and preferably plunger piston 106p may be coupled or otherwise associated with a cross linking member 114 may be utilized to couple at least one or more preferably a plurality of linear actuators 104. Optionally piston 106p may be coupled to cross linking member 114 via a coupling adaptor 116, 106c. Most preferably the linear motion of plunger 106, 16 is coupled to the movement of along the shaft of actuators 104, optionally directly and/or indirectly via a linking cross member 114. Preferably plunger 16,106 is therefore controlled to provide for controlling the flow through tube 12 by way of pinching to maintain control point 101 along tube 12 in optional positions selected from open, closed, partially open, or proportionally open or relative open percentage from about 0% (fully closed) to about 100% (fully open).

Optionally the number of actuators 104 utilized may be varied according to the pinch valve requirements. Optionally the number of actuators utilized may be controlled as a function of the flexible tube 12 utilized, size of tube 12, diameter of tube 12, materials of tube 12, flow rate requirements, the flowing fluid, the holding force required, the pinch valve parameters, the flow rate, the like or any combination thereof.

Most preferably actuator 104, depicted in greater detail in FIG. 3, is controlled with electronic circuitry module 108 which is connected thereto with connectors 104c.

Preferably housing 102 and more preferably upper portion 102a comprises a recess configured to receive and hold at least one or more actuators 104. Most preferably at least one end of actuators 104 is securely associated with housing 102 utilizing a holding plate 104h. Preferably holding plate 104h provides an anchoring point for at least one or more actuators 104. Preferably actuator 104 is anchored with plate 104h about at its non-free end comprising piezoelectric substrate and electrodes 104e and/or 104b, as shown in greater detail in FIG. 3.

FIG. 3 shows, preferably piezoelectric linear actuator 104 most preferably comprising a piezoelectric or electrostrictive substrate 104e, with an electrode provided on each of both surfaces (not shown) of the piezoelectric or electrostrictive substrate 104e ; an elastic body 104b, to one surface or each of both surfaces of which the piezoelectric or electrostrictive substrate 104e is attached; a movable shaft 104s coupled at an end thereof to the elastic body 104b or the piezoelectric or electrostrictive substrate 104e attached to the elastic body 104b, the movable shaft 104s may be operated in conjunction with displacement of the piezoelectric or electrostrictive substrate 104e ; and a movable body (114, 106) to be moved along the movable shaft.

Most preferably piezoelectric linear actuator 104 is securely associated with housing 102 via holding plate 104h that is coupled about elastic body 104b and/or 104e. Optionally housing 102 comprises a recess for accepting and/or receiving and/or fitting with elastic body 104b.

Most preferably the power profile provided to actuator substrate 104e is provided by a control signal (108s) from electronic circuitry (108) for controlling the power profile provided to electrodes (not shown) therein controlling the movement of plunger provides

FIG. 4A-B provides a detailed depiction of cross-linked load 114 that provides a cross-links for a plurality of piezoelectric valves 104 about their shafts 104s utilized in gating plunger assembly 106 relative to tube 12. Most preferably as shown in FIG. 2B plunger assembly 106 is coupled with cross linked load abut a central recess 114r. Cross link member allows the pinch valve assembly to harness the energy from a plurality of actuators 104, for example four as is shown. Optionally member 114 may be configured to cross link a plurality of actuators 104 according to pinch valve operational needs and/or parameters for example including but not limited to expected flow rate, flexible tube materials, diameter of tube 12, plunger size, plunger end, the like or any combination thereof.

FIGS. 7A-B, show cross linked-load member 114 that provides for linking four piezoelectric actuators 104 to control plunger 106 relative to flexible tube 12 at control segment 101 to provide fluid flow control through tube 12.

Optionally and preferably actuator cross-link load 114 provides for associating and/or coupling at least two or more, or a group of or a plurality of actuators 104 such that they act simultaneously and/or in a coordinated and/or concerted manner most preferably with collective force or thrust. Most preferably cross-link member 114 provides for coupling all actuators 104.

Preferably plunger 106 may be associated with cross linked load 114 via a central bore and/or recess 114r to provide for coupling and/or otherwise associating plunger 106 with module 100. Most preferably, when coupled, the movement of cross-linked load 114 controls the movement of plunger 216. The movement of load 114 is controlled with at least one or more piezoelectric actuators 104, about shafts 104s. Therein the movement of plunger 106is indirectly controlled by the movements provided by at least one or more actuators 104. For example, when load 114 is raised about shaft 104s, that in turn raises plunger 106 over flexible tube 12, therein allowing a fluid to flow through tube 12.

Most preferably the degree with which plunger 106is raised (‘opened’) relative to control point 101 defined along the length of tube 12 determines the flow rate through tube 12. Accordingly predictable, controllable and linear control of fluid flow through tube 12 is provided as direct and linear control of plunger 106 is provided by at least one and more preferably a plurality of piezoelectric actuators 104, via cross-linked load 114. Most preferably the valve assembly provides a holding force of up to about 2kg.

FIG. 4A shows a perspective view of a cross linked load 114 that provides for associating a plunger 106 about central recess 114r and up to four actuators 104 about shaft 104s through actuator shaft recess 114a.

FIG. 4A shows linked load 114 as a single member piece coupling up to four actuators 104. Cross-linked load 114 is shown in a particular “plus”, “+” shape configuration and geometry, specifically described in FIG. 4B, according to an optional embodiment of the present invention. Optionally and preferably, cross-linked load 114 comprises a central body 114c forming the core of load 114 with a plurality of extending arms 114e. Most preferably the number of extending arms 114e may be provided in relation to the number of actuators 104 utilized, for example as shown four arms corresponding to a four actuators 104 pinch valve gating module 100.

Most preferably core 114c comprises a bore and/or recess 114r for coupling with at least one plunger piston 106p. Most preferably arms 114e extend from core 114c, defining a proximal end 114p, adjacent to core 114c, and a distal end 114d. Most preferably distal end 114d comprises a recess 114a for accepting and/or holding or otherwise associating with at least one or more actuator 104 about at least a portion of actuator shaft 104s.

Optionally and preferably load 114 is provided from a single continuous, fluid material for example including but not limited to polymers, plastics, alloys, metals, metal alloys, any combination thereof or the like. Optionally load 114 may be configured from a plurality of member pieces that correspond to or otherwise couple or connect with one another. For example core 114c may provide a first member piece, while at least one or more extending arms may be provided from a second member piece that correspond or otherwise associate with core 114c.

Optionally cross-linked load 114 may be configured from at least two or more member pieces, to cross-link any number of actuators, for example a group of two, three, or more actuators. For example, cross-linked load 114 may be configured from two member piece therein linking, two adjacent actuators and/or two opposite actuators 104.

Optionally the cross linked-load member 114 may be provided in any optional geometric shape and/or configuration in order to meet valve requirements according to at least one or more parameters, for example including but not limited to type of valve, valve shape, valve body, number of actuators, type of actuators, actuator thrust, holding force requirements, number of valve stems, type of valve stem, direction of flow, number of direction flows, location of actuator shaft placement (recess 104a), any combination thereof or the like.

Optionally cross-linked load may be configured to control at least one or a plurality of plunger assembly 106 or plunger pistons 106p.

FIG. 4B provides a partial close up view of linked load 114 particularly showing extending arms 114e depicting an optional embodiment of the present invention. Extending arm 114e extends from and is fluid with load core 114c, defining a proximal end 114p and a distal end 114d. Arm 114e is characterized by having two substantially parallel extensions including, a base member 114b and a shaft support member 114s, separated by a recess 114a.

Optionally and preferably the geometry of recess 114a may be configured according to the dimension of actuator shaft 104s, for example shaft diameter or length, so as to optimize valve requirements in particular the holding force, and thrust provided by control module 100. Most preferably at least one dimension of recess 114a, for example width marked ‘Y’, is configurable according to actuator shaft 104s and valve requirements.

Most preferably base member 114b, as shown, is provided with a substantially quadrilateral geometric configuration in the form of a rectangle having width dimension ‘L’. Optionally and preferably the width ‘L’ of base member 114b may be configured according to the valve requirements. Optionally and preferably at least one surface of base member 114b or a portion thereof may be in contact with at least a portion of actuator shaft 104s, for example the luminal surface 114f, as shown. Optionally, in order to accommodate shaft 104s, the contact point between actuator shaft 104s and base member 114b about luminal surface 114f may be shaped and/or configured to according to the shape and/or configuration of shaft 104s to optimize the contact surface for example to provide further control for friction between shaft 104s and base 114b. For example the contact point about luminal surface 114f may be provided with a curvature for example to accommodate shaft 104s therein increasing the surface area in contact with base 114b and shaft 104s, for example providing for increased friction and/or resistance. Optionally, luminal surface 114f may be configured to minimize the contact point with shaft 104s and therein the surface area between them optionally leading to reduced friction and/or resistance between shaft 104s and luminal surface 114f.

Preferably shaft support member 114s is shaped and/or configured to receive actuator shaft 104s, for example as shown. Optionally and preferably shaft support member 114s comprises a dedicated portion for receiving and/or housing actuator shaft 104s, for example including a triangular shaft receiving portion 114t disposed bout the distal end of shaft support member 114s, as shown. Optionally receiving portion 114t may be disposed and/or placed anywhere along the length of shaft support member 114s, for example including but not limited to proximal portion, medial portion or distal portion (as shown). Optionally the shape of shaft receiving portion may be according to any geometric shape to define the number of contact points with actuator shaft 104s. For example, receiving portion 114t having a triangular configuration, as shown, comprises at least two contact points with actuator shaft 104s. Optionally receiving portion 114t may be provided with a quadrilateral configuration having at least three or more contact points with actuator shaft 104s. Optionally the shape and/or configuration of shaft receiving portion 114t may be configured to be any polygonal structure having ‘n’ sides (wherein n=3 or more) to define at least ‘n-1’ contact points with actuator shaft 104s.

Optionally and preferably the configuration of shaft receiving portion shaft support member 114s and/or receiving member 114t may be configurable about at least one or more parameters for example including but not limited to materials, material characteristics, material hardness, dimension, shape, thickness (‘Z’), length, distance from core 114c, distance from proximal end 114p (‘X’), shape, shaft contact points, shaft to receiving member 114t surface area, any combination thereof or the like. For example, as shown, the distance from the proximal end 114p to the center of receiving portion 114t may be configured according to distance marked ‘X’. For example, the thickness of shaft support member 114s may be configured according to thickness marked ‘Z’, as shown.

Optionally and most preferably, receiving portion 114t comprises a luminal surface 114h, facing recess 114a, a portion of which may be in contact with at least a portion of actuator shaft 104s, for example within recess 114a, as shown. Optionally, in order to accommodate shaft 104s, the contact point between actuator shaft 104s and receiving portion 114t about luminal surface 114h may be shaped and/or configured according to the shape and/or configuration of shaft 104s so as to optimize the contact surface there-between according to at least one or more valve requirements for example including but not limited to actuator thrust and valve holding force. Optionally and preferably configuring the luminal surface 114h may provide further control of friction between shaft 104s and support member 114s specifically receiving portion 114t. For example, the contact points about luminal surface 114f may be provided with a curvature, for example to accommodate shaft 104s therein increasing the surface area in contact with portion 114t and shaft 104s, for example providing for increased friction and/or resistance. Optionally, luminal surface 114h may be configured to minimize the contact point with shaft 104s and therein the surface area between them optionally leading to reduced friction and/or resistance between shaft 104s and luminal surface 114h.

As previously described, cross linked-load member 114 may be configured in order to meet pinch valve requirements according to at least one or more parameters, for example including but not limited to plunger end shape, number of actuators, type of actuators, actuator thrust, holding force requirements, number of valve stems, type of valve stem, direction of flow, number of direction flows, location of actuator shaft placement (recess 104a), any combination thereof or the like. Optionally and preferably cross-linked member 114s may be optimized and/or configured about extending arms 114e so as to account for valve requirements at least in configuring actuator thrust and valve holding force based on arm 114e dimension for example including but not limited to ‘L’, ‘X’, ‘Y’, ‘Z’, as shown and previously described. For example, changing the length of ‘X’ by a given distance has direct effect on the holding force and thrust of valve actuating module 210, for example, reducing ‘X’ by 0.2 mm may increase the valve holding force by 150g and thrust by 70g.

While the invention has been described with respect to a limited number of embodiment, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not described to limit the invention to the exact construction and operation shown and described and accordingly, all suitable modifications and equivalents may be resorted to, falling within the scope of the invention.

Having described a specific preferred embodiment of the invention with reference to the accompanying drawings, it will be appreciated that the present invention is not limited to that precise embodiment and that various changes and modifications can be effected therein by one of ordinary skill in the art without departing from the scope or spirit of the invention defined by the appended claims.

Further modifications of the invention will also occur to persons skilled in the art and all such are deemed to fall within the spirit and scope of the invention as defined by the appended claims.

While the invention has been described with respect to a limited number of embodiments, it will be appreciated that many variations, modifications and other applications of the invention may be made.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the scope of the appended claims.

Citation or identification of any reference in this application shall not be construed as an admission that such reference is available as prior art to the invention.

Section headings are used herein to ease understanding of the specification and should not be construed as necessarily limiting.

What is claimed is:

1) A control module (100) for controlling a pinch valve assembly (50,52,54,56) comprising at least one piezoelectric linear actuator (104) for controlling the flow through a flexible tube (12) disposed within a pinch valve body (10,110) by controlling the position of a plunger (106, 16) relative to said flexible tube (12) at a control point (101) along the length of said tube (12) , the control module (100) including:
a) a housing (102) having at least one surface adapted for associating with a pinch valve body (10, 110);
b) said housing (102) including at least one piezoelectric linear actuator (104) that is associated with a plunger (106, 16) to control the position of said plunger (16,106) relative to the flexible tube (12) for controlling the flow therethrought;
c) said piezoelectric linear actuator (104) comprising a piezoelectric or electrostrictive substrate (104e), with an electrode provided on each of both surfaces of the piezoelectric or electrostrictive substrate; an elastic body (104b), to one surface or each of both surfaces of which the piezoelectric or electrostrictive substrate (104e) is attached; a movable shaft (104s) coupled at an end thereof to the elastic body (104b) or the piezoelectric or electrostrictive substrate (104e) attached to the elastic body, the moveable shaft (104s) being operated in conjunction with displacement of the piezoelectric or electrostrictive substrate (104e); wherein the movement of said moveable shaft (104s) is controlled with a control signal (108s) produced by electronic circuitry (108) disposed in said housing (102), said circuitry (108) provided for controlling the power profile provided to said piezoelectric linear actuator (104), therein controlling the position of plunger (106, 16) associated therewith and the flow rate through said pinch valve body (10,110), characterized in that the flow rate though said valve body is configurable with said control signal (108s) such that said flow rate is proportional with said control signal (108s).

2) The device of claim 1 wherein the flow rate through said valve body (10) is linearly proportional with said control signal (108s).

3) The valve control module of claim 1 further comprising a processor for determining or configuring the correlation between said flow rate and said control signal.

4) The valve control module of claim 1 comprising a plurality of piezoelectric actuators (104).

5) The valve control module of claim 1 comprising at least four piezoelectric actuators (104).

6) The valve control module of claim 1 wherein said plunger (16,106) is associated with said piezoelectric linear actuator (104) utilizing a mediating member in the form of a cross linking load member (114).

7) The valve control module of claim 1 wherein said plunger (16,106) is directly associated with said piezoelectric linear actuator (104) by directly associating with said moveable actuator shaft (104s).

8) The valve control module of claim 1 wherein said piezoelectric linear actuator is controlled remotely with an auxiliary valve control module (20) producing a control signal (20s).

9) The valve control module of claim 1 wherein said valve body (10) is an off the shelf pinch valve body and wherein said housing (102) is configured to associate with said off the shelf pinch valve body (10) about said at least one member or surface (10a).

10) The valve control module of claim 9 configured to be retrofit with an off the shelf pinch valve body (10) wherein said valve control module (100) replaces the control module of the off the shelf pinch valve.

11) The valve control module of claim 9 wherein said off the shelf pinch valve body (10) comprises a recess to receive said plunger (106,16).

12) The valve control module of claim 1 wherein the pinch valve holding force exerted by said plunger is be configured to be from about 100g to about 2000g.

13) The valve control module of claim 1 wherein the pinch valve holding force about said plunger may be configured to be up to about 2000g.

14) The valve control module of claim 1 wherein the pinch valve holding force about said plunger may be configured to be up to about 1000g.

15) The valve control module of claim 6 wherein said cross linking load member (114) is configured to couple a plurality of piezoelectric actuators (104) about their actuator shaft (104s).

16) The valve control module of claim 6 wherein said cross linking load member (114) comprises:
a) a central body (114c) comprising a recess (114r) for coupling with a plunger;
b) at least one arm (114e) extending from said central body wherein said arm (114e) has a proximal end (114p) and a distal end (114d) wherein said proximal end extends from said central body and wherein said distal end (114d) associates with said actuator shaft (104s) about a recess (114a) for accepting said actuator shaft (104s);
c) said arm (114e) is characterized by having two substantially parallel extensions including, a base member (114b) and a shaft support member (114s), separated by said recess (114a) defining two opposing luminal surfaces (114f, 114h), wherein recess (114a) has a configurable dimension (‘Y’);
i) said base member (114b) defining at least one actuator shaft contact point about said first luminal surface (114f) within said recess (114a); wherein said base member (114b) has a configurable dimension (‘L’); and
ii) said shaft support member (114s) having a shaft receiving portion (114t) about said second luminal surface (114h) defining at least one or more actuator shaft contact points within said recess (114a); wherein said shaft support member (114s) has two configurable dimensions (‘Z’) and (‘X’) ; and
d) wherein said arm (114e) is configurable about at least one or any combination of parameters selected from the group consisting of material characteristics, material hardness, dimension (‘L’) of base portion (114b), dimension (‘Y’) of said shaft receiving recess (114a), dimension (‘Z’) of said shaft support member (114s), dimension (‘X’) defining the location of said shaft receiving portion (114t).

17) The valve control module of claim 16 wherein said arm (114e) is configured according to the required valve holding force.

18) The valve control module of claim 16 wherein the shape of said shaft receiving portion (114t) is configured to be triangular therein defining at least two actuator shaft contact points.

19) The valve control module of claim 16 wherein the shape of said shaft receiving portion (114t) is configured to be polygonal having n sides, wherein n is at least 3, therein defining at least n-1 actuator shaft contact points, about said second luminal surface (114h).

20) The valve control module of claim 16 wherein at least one dimension of said recess (114a) or said arm (114e) is configured according to a dimension of said actuator shaft (104s).

21) The valve control module of claim 16 wherein said cross linking load member (114) is configurable according to at least one or more of valve requirements selected from actuator thrust and valve holding force.

22) The valve control module of claim 21 wherein the valve holding force and actuator thrust of said moveable body (114) may be configured according to at least one or more selected from the group consisting of materials , material characteristics, material hardness, or any combination thereof.

23) The valve control module of claim 16 wherein said at least two luminal surfaces (114f, 114h) may be shaped and/or configured according to the shape and/or configuration of said actuator shaft (104s) so as to optimize the contact surface there-between, according to at least one or more valve requirements selected from the group consisting of actuator thrust and valve holding force.

24) The valve control module of claim 8 wherein said auxiliary control module (20) communicates a control signal (20s) using at least one or more communication protocols and/or technology selected from the group consisting of wireless, radio frequency (RF) , infrared (IR), optical, wired, near field communication (NFC), far field communication (FFC), RFID technology, acoustic, or any combination thereof.

25) The valve control module of claim 1 further comprising a strain gauge controller (105) provided for manually adjusting and/or fine tuning the movement of said plunger (16,106) relative to said control signal (108s).

26) The valve control module of claim 25 wherein said strain gauge (105) provides fine control of the force exerted by said plunger assembly (16,106) onto said flexible tube (12) at control segment (101).
